(19) United States
(12) Patent Application Publication
(10) Pub. No.: US 2015/0303145 A1
(43) Pub. Date: Oct. 22, 2015

(54) BACK END OF LINE (BEOL) LOCAL OPTIMIZATION TO IMPROVE PRODUCT PERFORMANCE

(71) Applicant: QUALCOMM Incorporated, San Diego, CA (US)

(72) Inventors: John Jianhong ZHU, San Diego, CA (US); PR CHIDAMBARAM, San Diego, CA (US); Giridhar NALLAPATI, San Diego, CA (US); Choh Fei YEAP, San Diego, CA (US)

(73) Assignee: QUALCOMM Incorporated, San Diego, CA (US)

(21) Appl. No.: 14/255,820

(22) Filed: Apr. 17, 2014

(51) Int. Cl. H01L 23/528; H01L 21/768; G06F 1/18

(52) U.S. Cl. CPC H01L 23/5283; G06F 1/18; H01L 21/76895

(57) ABSTRACT

The disclosure relates to a locally optimized integrated circuit (IC) including a first portion employing one or more metal interconnects having a first metal width and/or one or more vias having a first via width, and a second portion employing one or more metal interconnects having a second metal width and/or one or more vias having a second via width, wherein the second portion comprises a critical area of the IC, and wherein the second metal width is greater than the first metal width and the second via width is greater than the first via width. A method of locally optimizing an IC includes forming the one or more metal interconnects and/or the one or more vias in the first portion of the IC, and forming the one or more metal interconnects and/or the one or the more vias in the second portion of the integrated circuit.

### BACKGROUND OF THE DISCLOSURE

1. Field of the Disclosure

The disclosure is related to back end of line (BEOL) local optimization to improve product performance.

2. Description of the Related Art

The back end of line (BEOL) is the second portion of semiconductor fabrication, the process used to create an integrated circuit (IC), in which the individual components (e.g., transistors, capacitors, resistors, etc.) on the wafer are interconnected with wiring. After the last front end of line (FEOL) step, there is only a wafer with isolated components, meaning they are not connected to each other by any wires. The BEOL generally begins when the first layer of metal is deposited on the wafer. During the BEOL part of fabrication, contacts (pads), interconnect wires, vias, insulating layers (dielectrics), and bonding sites for chip-to-package connections are formed on the wafer. In the modern fabrication process, more than 10 metal layers can be added in the BEOL.

Improving the performance of ICs is a major goal. Typically, speed_push (i.e., increasing chip performance by certain means, including process optimization) or boosting product performance is done by improving the performance of the individual components (primarily transistors) on the IC. BEOL is becoming more and more important to product performance and could also contribute to speed_push. Traditional BEOL optimizations are accomplished by altering the global height and critical dimension (CD) of the metal interconnects. However, this does not always provide a sufficient increase in performance, particularly for system on a chip (SoC) ICs.

### SUMMARY

The disclosure is related to back end of line (BEOL) local optimization to improve product performance. A locally optimized integrated circuit includes a first portion employing one or more metal interconnects having a first metal width and/or one or more vias having a first via width, and a second portion employing one or more metal interconnects having a second metal width and/or one or more vias having a second via width, wherein the second portion comprises a critical area of the integrated circuit, and wherein the second metal width is greater than the first metal width and the second via width is greater than the first via width.

A locally optimized apparatus includes a first means including one or more metal interconnects having a first metal width and/or one or more vias having a first via width, and a second means including one or more metal interconnects having a second metal width and/or one or more vias having a second via width, wherein the second means comprises a critical area of the apparatus, and wherein the second metal width is greater than the first metal width and the second via width is greater than the first via width.

A method of locally optimizing an integrated circuit includes forming one or more metal interconnects having a first metal width and/or one or more vias having a first via width in a first portion of the integrated circuit, and forming one or more metal interconnects having a second metal width and/or one or more vias having a second via width in a second portion of the integrated circuit, wherein the second portion comprises a critical area of the integrated circuit, and wherein the second metal width is greater than the first metal width and the second via width is greater than the first via width.

An apparatus for locally optimizing an integrated circuit includes means for forming one or more metal interconnects having a first metal width and/or one or more vias having a first via width in a first portion of the integrated circuit, and means for forming one or more metal interconnects having a second metal width and/or one or more vias having a second via width in a second portion of the integrated circuit, wherein the second portion comprises a critical area of the integrated circuit, and wherein the second metal width is greater than the first metal width and the second via width is greater than the first via width.

A non-transitory computer-readable medium for locally optimizing an integrated circuit includes at least one instruction to cause a machine to form one or more metal interconnects having a first metal width and/or one or more vias having a first via width in a first portion of the integrated circuit, and at least one instruction to cause a machine to form one or more metal interconnects having a second metal width and/or one or more vias having a second via width in a second portion of the integrated circuit, wherein the second portion comprises a critical area of the integrated circuit, and wherein the second metal width is greater than the first metal width and the second via width is greater than the first via width.

### BRIEF DESCRIPTION OF THE DRAWINGS

A more complete appreciation of embodiments of the invention and many of the attendant advantages thereof will be readily obtained as the same becomes better understood by reference to the following detailed description when considered in connection with the accompanying drawings which are presented solely for illustration and not limitation of the invention, and in which:

FIG. 1 illustrates an exemplary system on a chip (SoC) integrated circuit (IC) that includes a central processing unit (CPU) and a graphics processing unit (GPU) according to an aspect of the disclosure.

FIG. 2 illustrates an exemplary SoC IC that includes a CPU and a GPU according to an aspect of the disclosure.

FIG. 3 illustrates an exemplary SoC IC that includes a CPU and a GPU according to an aspect of the disclosure.

FIG. 4 illustrates an exemplary apparatus according to an aspect of the disclosure.

FIG. 5 illustrates an exemplary flow for locally optimizing an apparatus according to an aspect of the disclosure.

### DETAILED DESCRIPTION

Aspects of the disclosure are described in the following description and related drawings directed to specific embodiments of the disclosure. Alternate embodiments may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any embodiment described herein as “exemplary” and/or “example” is not necessarily to be construed as preferred or advantageous over other embodiments. Likewise, the term “embodiments of the disclosure” does not require that all embodiments of the disclosure include the discussed feature, advantage, or mode of operation.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that, upon execution, would cause an associated processor to perform the functionality described herein. Thus, the various aspects of the disclosure may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

The disclosure is related to back end of line (BEOL) local optimization to improve product performance. The back end of line (BEOL) is the second portion of semiconductor fabrication, the process used to create an integrated circuit (IC), in which the individual components (e.g., transistors, capacitors, resistors, etc.) on the wafer are interconnected with wiring. After the last front end of line (FEOL) step, there is only a wafer with isolated components, meaning they are not connected to each other by any wires. The BEOL generally begins when the first layer of metal is deposited on the wafer. During the BEOL part of fabrication, contacts (pads), interconnect wires, vias, insulating layers (dielectrics), and bonding sites for chip-to-package connections are formed on the wafer. In the modern fabrication process, more than 10 metal layers can be added in the BEOL.

Improving the performance of ICs is a major goal in the art. Typically, speed_push or boosting product performance is done by improving the performance of the individual components on the IC. However, BEOL is becoming more and more important to product performance and could also contribute to speed_push. Traditional BEOL optimizations are accomplished by altering the global (i.e., applicable to the entire IC) height and critical dimension (CD) of the metal interconnects. This does not always provide a sufficient increase in performance, however, particularly for system on a chip (SoC) ICs.

An SoC IC typically includes both a central processing unit (CPU) and a graphics processing unit (GPU). A CPU and a GPU typically have different design and performance requirements. For example, a GPU typically requires a high density of BEOL interconnects, and therefore mainly uses minimal width and minimal space metals. On the other hand, CPU design pursues high performance, and therefore CPUs typically use relatively wide BEOL metal interconnects, as well as larger spaces between the interconnects. Consequently, global BEOL tuning (e.g., changing the height and/or CD of the metal interconnects throughout the entire IC, including both the CPU and GPU) may not be suitable for an SoC IC.

Accordingly, there is a need in the art to provide BEOL optimizations locally to improve product performance, and to boost product performance without causing global scale yield degradation. Such BEOL local optimization could help maximize product performance with minimum yield impact.

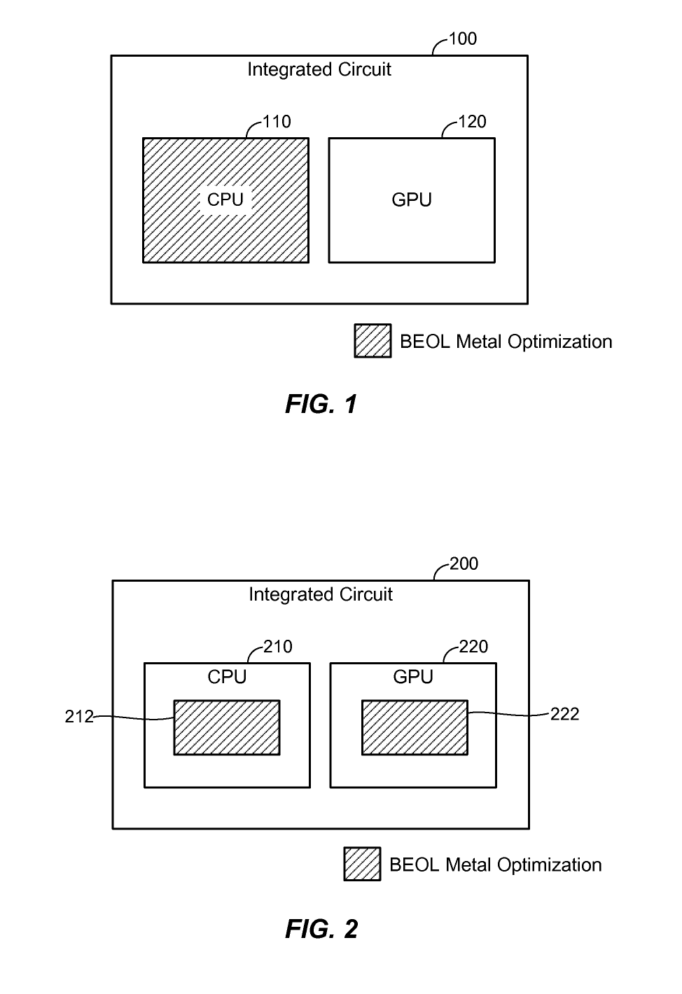

FIGS. 1-3 illustrate several BEOL local optimizations to improve product performance according to various aspects of the disclosure. FIG. 1 illustrates an SoC IC 100 that includes a CPU 110 and a GPU 120. Since a CPU may utilize relatively wide metal interconnects and/or relatively large spacing between the interconnects, there may be more room to selectively optimize the metal interconnects inside a CPU, as opposed to inside a GPU. For example, to improve the performance of the IC, the CD of the metal interconnects inside the CPU 110 can be increased by optical proximity correction (OPC), thereby lowering the resistance (R) of the metal, and also the RC (resistance×capacitance) of the metal or the BEOL delay. In the example of FIG. 1, CPU 110 has been optimized in this way, which is illustrated by cross-hatching CPU 110 and not GPU 120. This is a “local” optimization in that the changes to the width and spacing of the metal interconnects are only applied to the CPU 110, rather than to both the CPU 110 and the GPU 120 or the entire SoC IC 100.

FIG. 2 illustrates an exemplary SoC IC 200 that includes a CPU 210 and a GPU 220. Another option for BEOL local optimization is to increase and/or optimize the CD and/or spacing of the BEOL metal interconnects for only “critical” paths and/or areas within the CPU 210 and/or the GPU 220, where wider interconnects and/or greater spacing are often used. The areas within CPU 210 and GPU 220 that include these critical paths are illustrated as cross-hatched areas 212 and 222. This is a “local” optimization in that the changes to the width and spacing of the metal interconnects are only applied to critical paths and/or areas of the CPU 210 and/or the GPU 220, rather than to the entire CPU 210 and GPU 220, or to the entire SoC IC 200.

Although illustrated as a sub-area of the CPU 210, a “critical” area of an SoC IC may also be the entire CPU, as illustrated in FIG. 1.

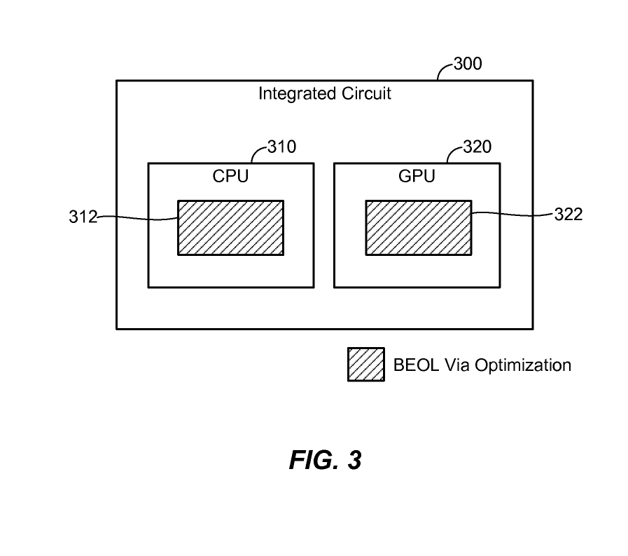

FIG. 3 illustrates an exemplary SoC IC 300 that includes a CPU 310 and a GPU 320. A third option for BEOL local optimization is to increase and/or optimize the CD of vias locally, e.g., only in critical areas or along critical paths of the CPU 310 and/or the GPU 320. Doing so lowers the resistance (R) of the vias and improves product performance. These “critical” areas with optimized vias are illustrated as cross-hatched areas 312 and 322. This is a “local” optimization in that the changes to the vias are only applied to critical paths and/or areas of the CPU 310 and/or the GPU 320, rather than to the entire CPU 310 and GPU 320, or the entire SoC IC 300.

FIGS. 1-3 are merely examples of BEOL local optimizations, and the disclosure is not limited to these examples. Rather, any optimization involving the height, width, and/or spacing of metal interconnects on an IC that are applied to less than the entire IC (and are thus “local”) are within the scope of this disclosure. Likewise, any optimization involving the height, width, and/or spacing of vias in an IC that are applied to less than the entire IC are within the scope of this disclosure.

Although not illustrated, these three example optimizations can be combined in any number of ways. For example, only the critical paths in a CPU may be optimized, rather than the entire CPU as in FIG. 1 or both the CPU and GPU as in FIGS. 2 and 3. As another example, both the metal interconnects and the vias on the critical paths of a CPU and/or a GPU may be optimized, rather than just one or the other as illustrated in FIGS. 2 and 3. As yet another example, the CPU and/or GPU may have multiple critical paths/areas, rather than just one as illustrated in FIGS. 2 and 3.

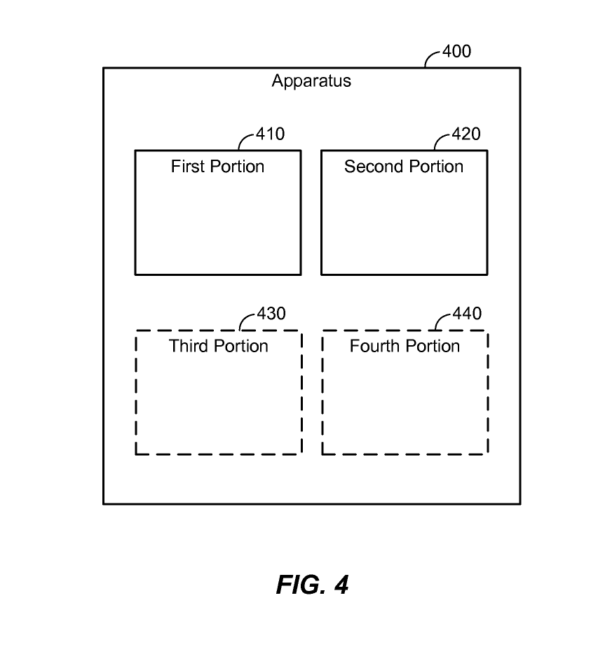

FIG. 4 illustrates an exemplary apparatus 400 according to an aspect of the disclosure. The apparatus 400 may be, for example, an integrated circuit, a microprocessor, a semiconductor, an application-specific integrated circuit (ASIC), a system on a chip (SoC), or any other circuit that is fabricated at least in part using BEOL. Apparatus 400 includes a first portion 410 employing one or more metal interconnects having a first metal width and/or one or more vias having a first via width. The apparatus 400 also includes a second portion 420 employing one or more metal interconnects having a second metal width and/or one or more vias having a second via width. The second portion 420 may be a critical area of the apparatus 400, and the second metal width may be greater than the first metal width and the second via width may be greater than the first via width. Although not illustrated as such, the first portion 410 may encompass the entire apparatus 400 except for the second portion 420.

Referring to the critical area, as an example, the critical area may be a CPU on the apparatus 400, or a sub-area of the CPU on the apparatus 400, or one or more paths within the CPU on the apparatus 400. Alternatively, the critical area may be a GPU on the apparatus 400, or a sub-area of the GPU on the apparatus 400, or one or more paths within the GPU on the apparatus 400. The critical area may also include a sub-area of the CPU on the apparatus 400 and a sub-area of the GPU on the apparatus 400.

The one or more metal interconnects having the second metal width may be formed during BEOL processing of the apparatus 400. Likewise, the one or more metal interconnects having the first metal width may be formed during BEOL processing of the apparatus 400. Similarly, the one or more vias having the first via width and the one or more vias having the second via width may be formed during BEOL processing of the apparatus 400.

The one or more metal interconnects employed in the first portion 410 may have a first metal height and the one or more metal interconnects employed in the second portion 420 may have a second metal height. As an example, the second metal height may be greater than the first metal height. Similarly, the one or more metal interconnects employed in the first portion 410 may have a first spacing and the one or more metal interconnects employed in the second portion 420 may have a second spacing. As an example, the second spacing may be greater than the first spacing.

The apparatus 400 may optionally include a third portion 430 employing one or more metal interconnects having a third metal width and/or one or more vias having a third via width. The third portion 430 may also be a critical area of the apparatus 400, and the third metal width may be greater than the first metal width and the third via width may be greater than the first via width. Since the third portion 430 may be a critical area, the third metal width may be the same as the second metal width. However, this is not necessary, and the third metal width may be different than the second metal width.

The apparatus 400 may also optionally include a fourth portion 440 employing one or more metal interconnects having a fourth metal width and/or one or more vias having a fourth via width. The fourth portion 440 may also be a critical area of the apparatus 400, and the fourth metal width may be greater than the first metal width and the fourth via width may be greater than the first via width. Since the fourth portion 440 may be a critical area, the fourth metal width may be the same as the second and third metal widths. However, this is not necessary, and the fourth metal width may be different than the second and third metal widths.

Although FIG. 4 illustrates three critical areas (i.e., portions 420-440), these are merely exemplary, and there may be any number of critical areas on apparatus 400. Further, the different portions 420-440 may be part of the same component (e.g., the CPU) or different component (e.g., the CPU and GPU).

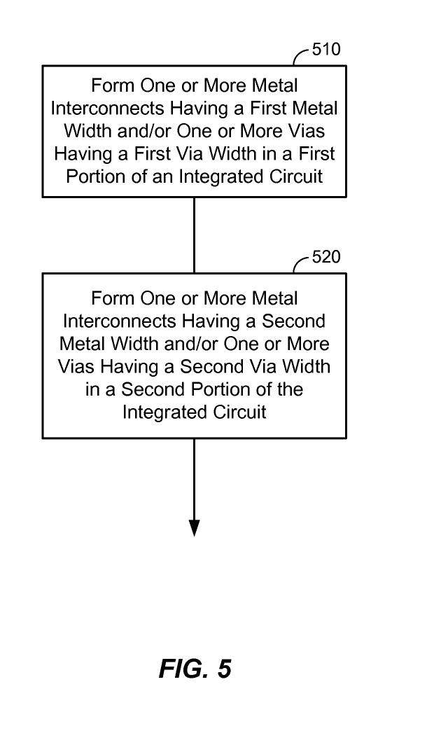

FIG. 5 illustrates an exemplary flow for locally optimizing an integrated circuit, such as apparatus 400. The flow illustrated in FIG. 5 may be performed by a machine during BEOL processing of the integrated circuit.

At 510, one or more metal interconnects having a first metal width and/or one or more vias having a first via width are formed in a first portion of the integrated circuit, such as first portion 410 in FIG. 4. At 520, one or more metal interconnects having a second metal width and/or one or more vias having a second via width are formed in a second portion of the integrated circuit, such as second portion 420. The second portion may be a critical area of the integrated circuit, and the second metal width may be greater than the first metal width and the second via width may greater than the first via width.

Referring to the critical area, as an example, the critical area may be a CPU on the integrated circuit, or a sub-area of the CPU on the integrated circuit, or one or more paths within the CPU on the integrated circuit. Alternatively, the critical area may be a GPU on the integrated circuit, or a sub-area of the GPU on the integrated circuit, or one or more paths within the GPU on the integrated circuit. The critical area may also include a sub-area of the CPU on the integrated circuit and a sub-area of the GPU on the integrated circuit.

The one or more metal interconnects having the first metal width and the one or more metal interconnects having the second metal width may be formed during BEOL processing of the integrated circuit. Similarly, the one or more vias having the first via width and the one or more vias having the second via width may be formed during BEOL processing of the integrated circuit.

Additionally, the one or more metal interconnects employed in the first portion may have a first metal height and the one or more metal interconnects employed in the second portion may have a second metal height. As an example, the second metal height may be greater than the first metal height. Similarly, the one or more metal interconnects employed in the first portion may have a first spacing and the one or more metal interconnects employed in the second portion may have a second spacing. As an example, the second spacing may be greater than the first spacing.

It will be appreciated that the flow illustrated in FIG. 5 may be embodied as a computer-readable medium, including a non-transitory computer-readable medium. Such a computer-readable medium may include at least one instruction to cause a machine to form one or more metal interconnects having a first metal width and/or one or more vias having a first via width in a first portion of the integrated circuit, and at least one instruction to cause a machine to form one or more metal interconnects having a second metal width and/or one or more vias having a second via width in a second portion of the integrated circuit, wherein the second portion comprises a critical area of the integrated circuit, and wherein the second metal width is greater than the first metal width and the second via width is greater than the first via width.

It will also be appreciated that the flow illustrated in FIG. 5 may be performed by a processor (or other logic circuit) executing instructions to cause a machine to perform the flow illustrated in FIG. 5 during BEOL processing of the integrated circuit. For example, a processor (or other logic circuit) may form one or more metal interconnects having a first metal width and/or one or more vias having a first via width in a first portion of the integrated circuit by executing at least one instruction to cause a machine to form the one or more metal interconnects having the first metal width and/or the one or more vias having the first via width. The processor (or other logic circuit) may form one or more metal interconnects having a second metal width and/or one or more vias having a second via width in a second portion of the integrated circuit by executing at least one instruction to cause a machine to form the one or more metal interconnects having the second metal width and/or the one or more vias having the second via width. The second portion comprises a critical area of the integrated circuit, and wherein the second metal width is greater than the first metal width and the second via width is greater than the first via width.

It will also be appreciated that the flow illustrated in FIG. 5 may be performed by a machine (or other apparatus) during BEOL processing of the integrated circuit. Such a machine (or other apparatus) may include means for forming one or more metal interconnects having a first metal width and/or one or more vias having a first via width in a first portion of the integrated circuit, and means for forming one or more metal interconnects having a second metal width and/or one or more vias having a second via width in a second portion of the integrated circuit, wherein the second portion comprises a critical area of the integrated circuit, and wherein the second metal width is greater than the first metal width and the second via width is greater than the first via width. Such “means” may include any BEOL machinery capable of performing the flow illustrated in FIG. 5.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A locally optimized integrated circuit, comprising:
a first portion employing one or more metal interconnects having a first metal width and/or one or more vias having a first via width; and
a second portion employing one or more metal interconnects having a second metal width and/or one or more vias having a second via width, wherein the second portion comprises a critical area of the integrated circuit, and wherein the second metal width is greater than the first metal width and the second via width is greater than the first via width.

2. The integrated circuit of claim 1, wherein the critical area comprises a central processing unit (CPU) on the integrated circuit.

3. The integrated circuit of claim 1, wherein the critical area comprises a graphics processing unit (GPU) on the integrated circuit.

4. The integrated circuit of claim 1, wherein the critical area comprises a sub-area of a CPU on the integrated circuit.

5. The integrated circuit of claim 1, wherein the critical area comprises a sub-area of a CPU on the integrated circuit and a sub-area of a GPU on the integrated circuit.

6. The integrated circuit of claim 1, wherein the critical area comprises one or more paths within a CPU on the integrated circuit.

7. The integrated circuit of claim 1, wherein the one or more metal interconnects having the second metal width are formed during back end of line (BEOL) processing of the integrated circuit.

8. The integrated circuit of claim 1, wherein the one or more vias having the second via width are formed during BEOL processing of the integrated circuit.

9. The integrated circuit of claim 1, wherein the one or more metal interconnects employed in the first portion have a first metal height and the one or more metal interconnects employed in the second portion have a second metal height, and wherein the second metal height is greater than the first metal height.

10. The integrated circuit of claim 1, wherein the one or more metal interconnects employed in the first portion have a first spacing and the one or more metal interconnects employed in the second portion have a second spacing, and wherein the second spacing is greater than the first spacing.

11. The integrated circuit of claim 1, further comprising:
a third portion employing one or more metal interconnects having a third metal width and/or one or more vias having a third via width, wherein the third portion comprises a critical area of the integrated circuit, and wherein the third metal width is greater than the first metal width and the third via width is greater than the first via width.

12. The integrated circuit of claim 11, wherein the third metal width is the same as the second metal width.

13. The integrated circuit of claim 11, wherein the third metal width is different than the second metal width.

14. The integrated circuit of claim 1, wherein the first portion encompasses the entire integrated circuit except for the second portion.

15. A method of locally optimizing an integrated circuit, comprising:
forming one or more metal interconnects having a first metal width and/or one or more vias having a first via width in a first portion of the integrated circuit; and
forming one or more metal interconnects having a second metal width and/or one or more vias having a second via width in a second portion of the integrated circuit, wherein the second portion comprises a critical area of the integrated circuit, and wherein the second metal width is greater than the first metal width and the second via width is greater than the first via width.

16. The method of claim 15, wherein the critical area comprises a central processing unit (CPU) on the integrated circuit.

17. The method of claim 15, wherein the critical area comprises a graphics processing unit (GPU) on the integrated circuit.

18. The method of claim 15, wherein the critical area comprises a sub-area of a CPU on the integrated circuit.

19. The method of claim 15, wherein the critical area comprises a sub-area of a CPU on the integrated circuit and a sub-area of a GPU on the integrated circuit.

20. The method of claim 15, wherein the critical area comprises one or more paths within a CPU on the integrated circuit.

21. The method of claim 15, wherein the one or more metal interconnects having the second metal width are formed during back end of line (BEOL) processing of the integrated circuit.

22. The method of claim 15, wherein the one or more vias having the second via width are formed during BEOL processing of the integrated circuit.

23. The method of claim 15, wherein the one or more metal interconnects employed in the first portion have a first metal height and the one or more metal interconnects employed in the second portion have a second metal height, and wherein the second metal height is greater than the first metal height.

24. The method of claim 15, wherein the one or more metal interconnects employed in the first portion have a first spacing and the one or more metal interconnects employed in the second portion have a second spacing, and wherein the second spacing is greater than the first spacing.

25. The method of claim 15, further comprising:
forming one or more metal interconnects having a third metal width and/or one or more vias having a third via width in a third portion of the integrated circuit, wherein the third portion comprises a critical area of the integrated circuit, and wherein the third metal width is greater than the first metal width and the third via width is greater than the first via width.

26. The integrated circuit of claim 25, wherein the third metal width is the same as the second metal width.

27. The integrated circuit of claim 25, wherein the third metal width is different than the second metal width.

28. The integrated circuit of claim 15, wherein the first portion encompasses the entire integrated circuit except for the second portion.

29. A locally optimized apparatus, comprising:
a first means including one or more metal interconnects having a first metal width and/or one or more vias having a first via width; and
a second means including one or more metal interconnects having a second metal width and/or one or more vias having a second via width, wherein the second means comprises a critical area of the apparatus, and wherein the second metal width is greater than the first metal width and the second via width is greater than the first via width.

30. A non-transitory computer-readable medium for locally optimizing an integrated circuit, comprising:
at least one instruction to cause a machine to form one or more metal interconnects having a first metal width and/or one or more vias having a first via width in a first portion of the integrated circuit; and
at least one instruction to cause a machine to form one or more metal interconnects having a second metal width and/or one or more vias having a second via width in a second portion of the integrated circuit, wherein the second portion comprises a critical area of the integrated circuit, and wherein the second metal width is greater than the first metal width and the second via width is greater than the first via width.
